(19) United States
(12) Patent Application Publication
(10) Pub. No.: US 2018/0096892 A1
(43) Pub. Date: Apr. 5, 2018

(54) DEVICE WAFER PROCESSING METHOD

(71) Applicant: DISCO CORPORATION, Tokyo (JP)

(72) Inventor: Hideyuki Sandoh, Tokyo (JP)

(21) Appl. No.: 15/721,036

(22) Filed: Sep. 29, 2017

(30) Foreign Application Priority Data
Sep. 30, 2016 (JP) 2016-194251

(51) Int. Cl. H01L 21/78; H01L 21/304; H01L 21/3065; H01L 21/683

(52) U.S. Cl. CPC H01L 21/78; H01L 21/304; H01L 2221/68327; H01L 21/6836; H01L 2221/6834; H01L 21/3065

(57) ABSTRACT

A device wafer processing method includes forming a mask patterned so as to cover plural devices formed on a front side of the wafer and expose streets between the devices, applying plasma through the mask to thereby form a groove along each street, the groove having a depth corresponding to a finished thickness of the devices and having a reverse tapering shape such that the distance between opposed side walls of the groove is increased with an increase in depth of the groove, removing the mask, attaching a protective member to the front side of the wafer, and then grinding a back side of the wafer until the bottom of the groove is exposed, thereby reducing the thickness of the wafer to the finished thickness to divide the wafer into a plurality of device chips.

### BACKGROUND OF THE INVENTION

### Field of the Invention

The present invention relates to a device wafer processing method for dividing a device wafer into individual device chips.

### Description of the Related Art

Conventionally known is a device wafer processing method for dividing a device wafer into individual device chips, wherein the device wafer has a substrate and a plurality of devices formed on a front side of the substrate, and a plurality of crossing streets (division lines) are formed on the front side of the substrate to thereby define a plurality of separate regions where the plural devices are individually formed, the device wafer being divided along these streets to obtain the individual device chips. In this kind of processing method, plasma is applied to the front side of the device wafer in the condition where each device is protected by a water-soluble protective film, thereby etching the substrate along each street to divide the device wafer into the individual device chips (see U.S. Pat. No. 8,703,581, for example). Further, it is also known that plasma is applied to the device wafer to etch the front side of the substrate along each street, thereby forming a groove on the front side of the substrate along each street, the groove having a depth corresponding to the finished thickness of each device chip, and that a back side of the device wafer is next ground in the condition where a protective member is attached to the front side of the device wafer, thereby dividing the device wafer into the individual device chips (see Japanese Patent Laid-Open No. 2015-220366, for example).

### SUMMARY OF THE INVENTION

In the case that plasma is applied to the device wafer to etch it from the front side to the back side, thereby fully divide the device wafer into the device chips, there is a possibility that the protective film protecting the device wafer is exposed to the plasma and may be damaged by the plasma. Further, in the case that plasma is applied to the device wafer to form a groove having a depth corresponding to the finished thickness of each device chip and that the back side of the device wafer is next ground to divide the device wafer, there is a possibility that the corners of the adjacent device chips may be rubbed with each in grinding the device wafer, causing a reduction in processing quality of each device chip.

It is therefore an object of the present invention to provide a device wafer processing method which can form individual device chips with good processing quality.

In accordance with an aspect of the present invention, there is provided a device wafer processing method for processing a device wafer having a substrate and a plurality of devices formed on a front side of the substrate, a plurality of crossing streets being formed on the front side of the substrate to thereby define a plurality of separate regions where the devices are individually formed. The device wafer processing method includes a mask forming step, a groove forming step, a mask removing step, a protective member attaching step, and a dividing step. The mask forming step forms a mask patterned so as to cover the devices and expose the front side of the substrate in a region corresponding to each street. The groove forming step applies plasma through the mask to a front side of the wafer to thereby form a groove on the front side of the wafer along each street, the groove having a depth corresponding to a finished thickness of the device and having a reverse tapering shape such that a distance between opposed side walls of the groove is increased with an increase in depth of the groove. The mask removing step removes the mask from the front side of the wafer after performing the groove forming step. The protective member attaching step attaches a protective member to the front side of the wafer after performing the mask removing step. The dividing step holds the front side of the wafer through the protective member on a chuck table and then grinds a back side of the wafer until a bottom of the groove is exposed to the back side of the wafer, thereby reducing the thickness of the wafer to the finished thickness to divide the wafer into a plurality of device chips.

In accordance with another aspect of the present invention, there is provided a device wafer processing method for processing a device wafer having a substrate, a plurality of devices formed on a front side of the substrate, and a passivation film covering the devices, a plurality of crossing streets being formed on the front side of the substrate to thereby define a plurality of separate regions where the devices are individually formed, the front side of the substrate in a region corresponding to each street being exposed. The device wafer processing method includes a groove forming step, a protective member attaching step, and a dividing step. The groove forming step applies plasma through the passivation film as a mask to a front side of the wafer to thereby form a groove on the front side of the wafer along each street, the groove having a depth corresponding to a finished thickness of the device and having a reverse tapering shape such that a distance between opposed side walls of the groove is increased with an increase in depth of the groove. The protective member attaching step attaches a protective member to the front side of the wafer after performing the groove forming step. The dividing step holds the front side of the wafer through the protective member on a chuck table and then grinds a back side of the wafer until a bottom of the groove is exposed to the back side of the wafer, thereby reducing the thickness of the wafer to the finished thickness to divide the wafer into a plurality of device chips.

In the above configuration, the groove formed on the front side of the wafer along each street by the plasma etching has a reverse tapering shape such that the distance between the opposed side walls of the groove is increased with an increase in depth of the groove.

As described above, the groove forming step is performed to form the groove on the front side of the wafer along each street, wherein each groove has a depth corresponding to the finished thickness of the wafer, i.e., each device chip. Further, each groove has a reverse tapering shape such that the distance between the opposed side walls is increased with an increase in depth of each groove. With this configuration, in grinding the back side of the wafer to divide the wafer into the individual device chips, it is possible to suppress that the side walls and corners of the adjacent device chips may rub each other, so that each device chip can be obtained with high quality. Further, each groove formed on the front side of the device wafer by the plasma etching in the groove forming step has a depth corresponding to the finished thickness of each device chip, and this depth of each groove does not reach the back side of the device wafer. Accordingly, in performing the plasma etching, it is possible to prevent that a support member such as a dicing tape attached to the back side of the wafer may be exposed to the plasma. As a result, damage to the support member by the plasma can be suppressed.

According to the present invention, the groove formed on the front side of the device wafer along each street has a reverse tapering shape such that the distance between the opposed side walls is increased with an increase in depth of the groove. With this configuration, in grinding the back side of the wafer to divide the wafer into the individual device chips, it is possible to suppress that the side walls and corners of the adjacent device chips may rub each other, so that each device chip can be obtained with high quality.

The above and other objects, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1 is a perspective view of a device wafer as a workpiece to be processed by a device wafer processing method according to a first preferred embodiment of the present invention;

FIG. 2 is a flowchart showing the procedure of the device wafer processing method according to the first preferred embodiment;

FIG. 3 is a sectional view of the wafer in the condition where plural devices formed on a front side of the wafer are masked by a resist film;

FIG. 4 is a sectional view showing a groove formed along each street on the front side of the wafer;

FIG. 5 is an enlarged sectional view of the groove shown in FIG. 4;

FIG. 6 is a sectional view of the wafer in the condition where a back grind tape is attached to the front side of the wafer;

FIG. 7 is a sectional view of the wafer in the condition just before grinding a back side of the wafer;

FIG. 8 is a sectional view of device chips divided from the wafer by grinding the back side of the wafer;

FIG. 9 is a flowchart showing the procedure of a device wafer processing method according to a second preferred embodiment of the present invention;

FIG. 10 is a sectional view of the wafer in the condition where plural devices formed on the front side of the wafer are masked by a passivation film;

FIG. 11 is a sectional view showing a groove formed along each street on the front side of the wafer;

FIG. 12 is a sectional view of the wafer in the condition where a back grind tape is attached to the front side of the wafer;

FIG. 13 is a sectional view of the wafer in the condition just before grinding the back side of the wafer; and

FIG. 14 is a sectional view of device chips divided from the wafer by grinding the back side of the wafer.

### DETAILED DESCRIPTION OF THE PREFERRED EMBODIMENTS

Preferred embodiments of the present invention will now be described in detail with reference to the drawings. The present invention is not limited to the preferred embodiments. Further, the components used in the preferred embodiments may include those that can be easily assumed by persons skilled in the art or substantially the same elements as those known in the art. Further, the configurations described below may be suitably combined. Further, the configurations may be variously omitted, replaced, or changed without departing from the scope of the present invention.

### First Preferred Embodiment

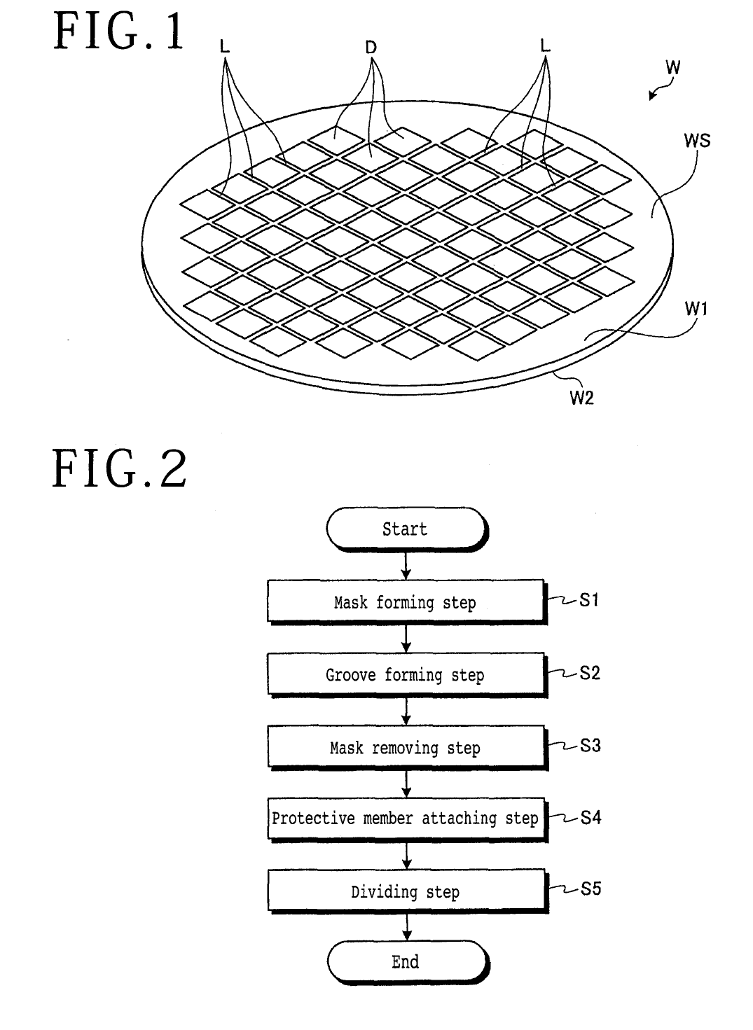

FIG. 1 is a perspective view of a device wafer as a workpiece to be processed by a device wafer processing method according to a first preferred embodiment of the present invention. As shown in FIG. 1, a device wafer W (which will be hereinafter referred to simply as wafer W) has a disk-shaped substrate WS formed of silicon, sapphire, or gallium arsenide, for example, as a base material. The substrate WS (wafer W) has a front side (one side) W1 and a back side (the other side) W2. A plurality of crossing streets (division lines) L are formed on the front side W1 of the substrate WS to thereby define a plurality of rectangular separate regions where a plurality of devices D are individually formed. Further, a dicing tape (not shown) as a support member is attached to the back side W2 of the substrate WS, and an annular frame (not shown) is mounted on the peripheral portion of the dicing tape so as to surround the wafer W. Accordingly, the wafer W is supported through the dicing tape to the annular frame.

The processing method for the wafer W will now be described. The device wafer processing method according to the preferred embodiment is a method for dividing the wafer W along the streets L into the separate regions (device chips) individually including the devices D. As the method for dividing the wafer W into the device chips, a plasma etching method is useful. The plasma etching method includes the steps of masking the separate regions including the devices D on the front side W1 of the substrate WS to expose the other regions corresponding to the streets L and next plasma-etching the other regions corresponding to the streets L exposed. In this method, a groove having a depth corresponding to the finished thickness of each device chip is formed on the front side W1 of the wafer W along each street L by applying plasma. Thereafter, a protective member is attached to the front side W1 of the wafer W, and the back side W2 of the wafer W is next ground until the bottom of each groove is exposed to the back side W2, thereby dividing the wafer W into the individual device chips.

Although the front side W1 of the wafer W is protected by the protective member in this method, there is a possibility that the corners of the device chips may be rubbed with each other in grinding the back side W2 of the wafer W, causing a reduction in processing quality of each device chip. In recent years, there has been a trend that each device chip is reduced in size. That is, the recent trend is that the thickness of the wafer W is reduced to a range (e.g., in the range from 30 to 100 μm) smaller than a predetermined thickness (e.g., 300 μm) and that the width of each street L is also reduced to a predetermined range (e.g., in the range from 10 to tens of μm). Accordingly, in the case of dividing such a wafer W reduced in thickness and having narrow streets L by adopting plasma etching, it is considered that the possibility of a quality reduction in each device chip may be increased. In the preferred embodiment, it is important that rubbing of the side walls and corners of the device chips can be suppressed in grinding the back side of the wafer, thereby forming each device chip with good processing quality. FIG. 2 is a flowchart showing the procedure of the device wafer processing method according to the first preferred embodiment. As shown in FIG. 2, the device wafer processing method according to the first preferred embodiment includes a mask forming step S1, a groove forming step S2, a mask removing step S3, a protective member attaching step S4, and a dividing step S5. The order of the steps mentioned above is not limited to that shown in FIG. 2. These steps will now be described.

### (Mask Forming Step S1)

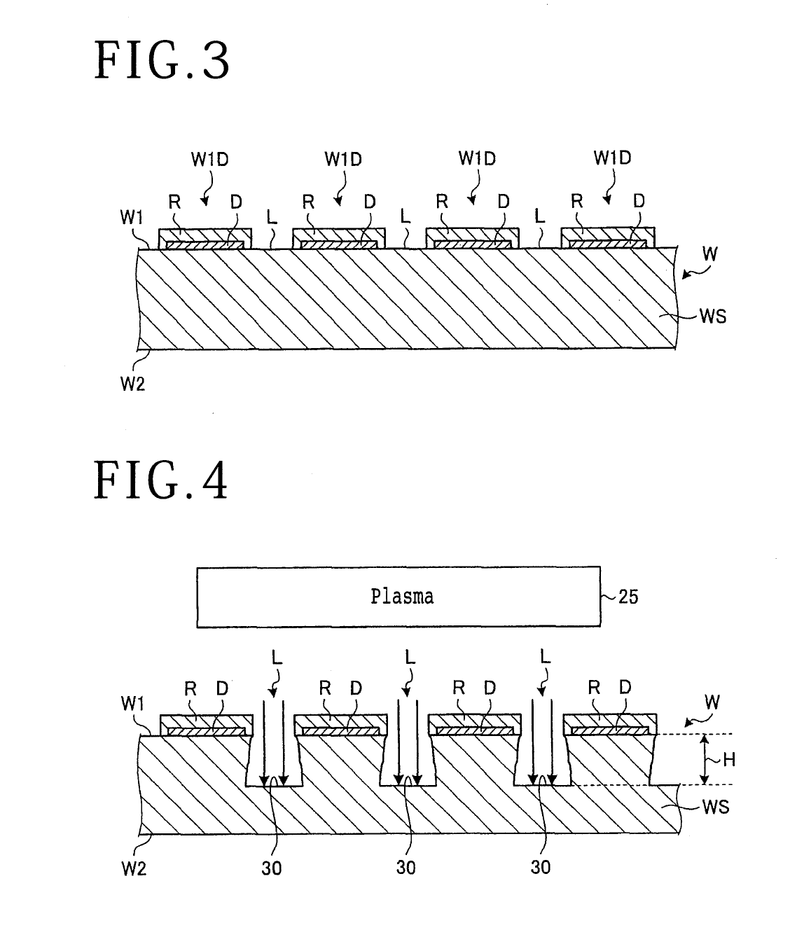

FIG. 3 is a sectional view of the wafer in the condition where the plural devices formed on the front side of the wafer are masked by a resist film. As shown in FIG. 3, a resist film R as a patterned mask is formed on the front side W1 of the wafer W. More specifically, the resist film R is formed on the front side W1 so as to cover plural device corresponding regions W1D as the regions corresponding to the plural devices D formed on the front side W1 of the wafer W. In this case, the resist film R is not formed on the streets L, so that the streets L are exposed. For example, the resist film R may be formed of resin such as polyimide resin, epoxy resin, and acrylic resin. Further, a photoresist may also be used as the resist film R, wherein when light or ultraviolet radiation is applied to the photoresist, the structure of the photoresist is changed.

In the case of using a photoresist as the resist film R, the photoresist is first applied to the whole surface of the front side W1 by using a spin coater or the like. Thereafter, the streets L formed on the front side W1 are recognized by using a camera or the like. Thereafter, ultraviolet radiation (or X-ray) is applied to the photoresist through a photomask having a lattice pattern corresponding to the shape of the crossing streets L. In the case that the photoresist is a negative photoresist, the photoresist present in the device corresponding regions W1D of the front side W1 is exposed to light. When the exposed portion of the photoresist is developed, only the photoresist present on the streets L formed on the front side W1 is removed, so that the resist film R is left in only the device corresponding regions W1D. While the resist film R is formed from the negative photoresist having the property that the exposed portion is left after development in the above case, a positive photoresist may also be used as the resist film R. In the case of using a positive photoresist, an exposed portion of the positive photoresist is removed after development. In this case, a photomask having an opening corresponding to the crossing streets L may be used, and the positive photoresist is exposed to light through this opening of the photomask.

As a modification, the resist film R may be replaced by a protective film as a mask, wherein the protective film is formed by applying a liquid resin to the device corresponding regions W1D of the front side W1. As the liquid resin, a water-soluble resin may be used. Examples of the water-soluble resin includes polyvinyl alcohol (PVA), polyethylene glycol (PEG), polyvinyl pyrrolidone (PVP), polyethylene oxide, polyethylene imide, carboxy methyl cellulose, and hydroxy ethyl cellulose. The patterned protective film can be formed by mounting a mold having an opening corresponding to the device corresponding regions W1D on the front side W1 of the wafer W and next filling this opening of the mold with the liquid resin. As a modification, the resist film R or the protective film may be patterned by forming a mask on the whole surface of the front side W1 and next applying a laser beam to the regions corresponding to the streets L to thereby perform laser ablation, i.e., to thereby expose the streets L.

### (Groove Forming Step S2)

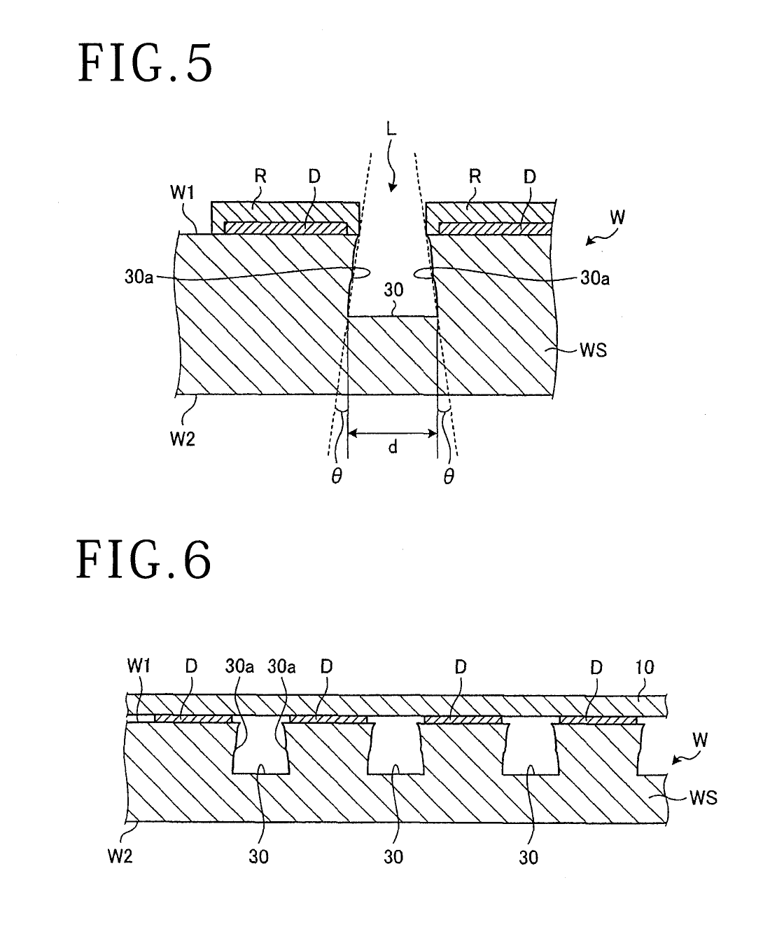

After performing the mask forming step S1, plasma etching is performed to the wafer W, thereby forming a groove 30 along each street L on the front side W1 of the wafer W. FIG. 4 is a sectional view showing the groove formed along each street on the front side of the wafer. FIG. 5 is an enlarged sectional view of the groove shown in FIG. 4. As shown in FIG. 4, the wafer W is held in a vacuum chamber (not shown) of a plasma etching apparatus (not shown) in the condition where the back side W2 of the wafer W is oriented downward, i.e., the front side W1 of the wafer W is exposed. In this condition, plasma is applied to the front side W1 of the wafer W to thereby form the groove 30 along each street L on the front side W1 of the wafer W, wherein the groove 30 has a depth corresponding to the finished thickness H of each device chip. As shown in FIG. 5, the groove 30 has opposed side walls 30a spaced a distance d from each other, wherein the distance d between the opposed side walls 30a of the groove 30 is gradually increased from the front side W1 (upper surface) toward the back side W2 (lower surface) (i.e., gradually increased with an increase in depth of the groove 30). In other words, the groove 30 has a reverse tapering shape as viewed in cross section in such a manner that the width of the groove 30 is gradually increased with an increase in depth of the groove 30. In actual, a plurality of asperities are formed on each side wall 30a of the groove 30 in performing the plasma etching. Accordingly, it is sufficient that the sectional shape of the groove 30 must be a reverse tapering shape as a whole. That is, the distance d between the opposed side walls 30a of the groove 30 may be locally smaller than the width of the upper end of the groove 30 opening to the front side W1.

The opposed side walls 30a of the groove 30 will become inclined side surfaces of the adjacent device chips in the future. As shown in FIG. 5, each side wall 30a is inclined by an angle θ with respect to the thickness direction of the wafer W, i.e., with respect to a normal to the front side W1 of the wafer W. This inclination angle θ is set to a value greater than 0 degree and less than or equal to a predetermined value (e.g., 30 degrees), preferably in the range of 5 to 15 degrees. If the inclination angle θ is less than or equal to 0 degree, there arises a problem that when the back side W2 of the wafer W is ground to divide the wafer W into the device chips in the dividing step S5 to be performed later, the edge portion of each side wall on the back side of each device chip projects more than the edge portion on the front side of each device chip, causing easy rubbing of the adjacent device chips. Further, if the inclination angle θ is greater than the predetermined value, chipping of each device chip may easily occur.

The groove 30 having a reverse tapering shape is formed by using a so-called BOSCH Process, wherein plasma etching and deposition (side wall protection film deposition) are repeated. Further, in the preferred embodiment, the plasma etching is composed of isotropic etching and anisotropic etching, which are alternately performed. For example, the plasma etching is performed in the following manner. In the condition where the wafer W is held in a vacuum chamber (not shown), an etching gas (e.g., SF₆) is supplied toward the front side W1 of the wafer W. In this condition where the etching gas is supplied, a radio frequency (RF) power is applied between an upper electrode (not shown) opposed to the front side W1 of the wafer W and a lower electrode (not shown) opposed to the back side W2 of the wafer W, thereby producing plasma 25 as shown in FIG. 4. The plasma 25 is applied to the front side W1 of the wafer W along the streets L exposed.

The isotropic etching is performed in the following manner. Under radical rich conditions where the etching species contributing to etching are mainly radicals (e.g., obtained by stopping the application of an RF bias to the lower electrode), it is suppressed that ions in the plasma 25 strike the front side W1 of the wafer W perpendicularly thereto, so that the ions strike the front side W1 in all directions (isotropically). In contrast, the anisotropic etching is performed in such a manner that the ions in the plasma 25 strike the front side W1 of the wafer W perpendicularly thereto. The above-mentioned radical rich conditions may be obtained by any methods other than the method of stopping the application of an RF bias to the lower electrode. For example, a mesh plate formed of metal such as aluminum may be located between the upper electrode and the lower electrode, and the ions may be deactivated by this mesh plate.

Further, the deposition is performed in the following manner. An etching gas (e.g., C₄F₈) is supplied toward the front side W1 of the wafer W. In the condition where this etching gas is supplied, an RF power is applied between the upper electrode and the lower electrode to thereby produce plasma 25, so that a fluorocarbon film as a protective film is deposited on the inner surface of the groove 30 formed along each street L.

More specifically, the groove forming step S2 is performed in the following manner. First, the front side W1 of the wafer W in the regions corresponding to the streets L is subjected to the plasma etching. Thereafter, the deposition is performed to form a fluorocarbon film on the inner surface of each groove 30. Thereafter, an RF bias is applied to perform anisotropic etching, so that the fluorocarbon film deposited on the bottom surface of each groove 30 is removed and the base material of the wafer W is exposed to the bottom surface of each groove 30. Thereafter, the application of the RF bias to the substrate is stopped to thereby perform isotropic etching. The deposition, the anisotropic etching, and the isotropic etching are performed in series as one cycle. The conditions in one cycle, e.g., the duration of each process, may be gradually changed and plural cycles may be repeatedly performed to thereby form each groove 30 having a reverse tapering shape. For example, by gradually increasing the duration of the isotropic etching in one cycle, the distance d between the opposed side walls 30a of each groove 30 can be gradually increased to thereby form each groove 30 having a reverse tapering shape. As a modification, by changing the area of the fluorocarbon film to be removed by the anisotropic etching (e.g., by changing the area of the base material of the substrate to be exposed to the bottom surface of each groove 30 by the anisotropic etching), each groove 30 having a reverse tapering shape can be formed. The anisotropic etching and the isotropic etching are not limited to the above methods, but various known methods may be adopted. Further, the shape of each side wall 30a shown in FIGS. 4 and 5 is a deformed shape of the plural asperities formed in etching the wafer W. In actual, the number of the plural asperities changes according to the number of the cycles each composed of the deposition, the anisotropic etching, and the isotropic etching.

### (Mask Removing Step S3)

When the depth of each groove 30 reaches the finished thickness H of each device chip in the groove forming step S2, the plasma etching is finished and the resist film R is next removed from the front side W1 of the wafer W as shown in FIG. 6. The resist film R may be removed by exposing the wafer W to a resist stripper or by ashing using an oxygen plasma. In the case that a water-soluble protective film is used as the mask, the protective film can be removed by supplying water (pure water) to the front side W1 of the wafer W. In the condition where the resist film R or the protective film as the mask has been removed, the devices D are exposed again to the front side W1 of the wafer W.

### (Protective Member Attaching Step S4)

FIG. 6 is a sectional view of the wafer in the condition where a back grind tape is attached to the front side of the wafer. After performing the mask removing step S3, a back grind tape (BG) (protective member) 10 is attached to the front side W1 of the wafer W as shown in FIG. 6. The back grind tape 10 functions to protect the devices D formed on the front side W1 of the wafer W and also to support the device chips to be divided from the wafer W by grinding the back side W2 of the wafer W in the next dividing step S5. The back grind tape 10 is attached through a paste layer (adhesive) to the front side W1 of the wafer W, wherein the paste layer has an adhesive force to be reduced by applying ultraviolet light having a predetermined wavelength (e.g., 300 to 400 nm).

### (Dividing Step S5)

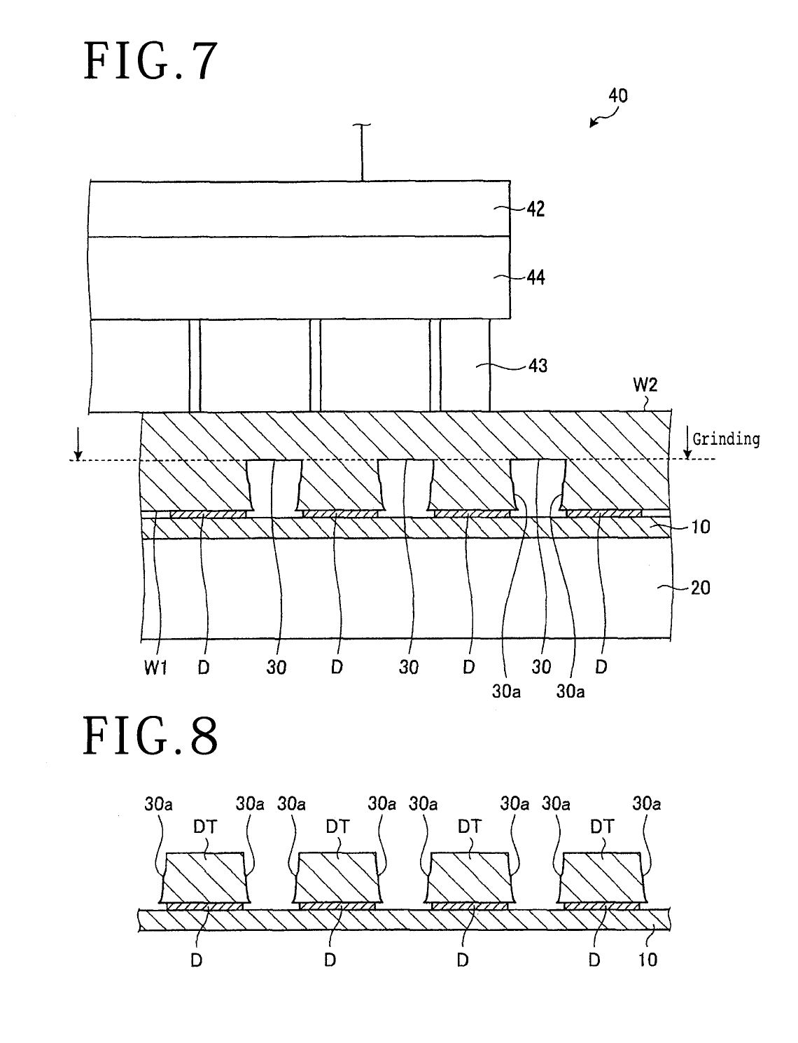

After performing the protective member attaching step S4, a dividing step S5 is performed to grind the back side W2 of the wafer W until the thickness of the wafer W is reduced to the predetermined finished thickness H, thereby dividing the wafer W into the individual device chips. FIG. 7 is a sectional view of the wafer in the condition just before grinding the back side of the wafer. FIG. 8 is a sectional view of the device chips divided from the wafer by grinding the back side of the wafer. Prior to grinding the back side W2 of the wafer W, the dicing tape (not shown) is peeled from the back side W2 of the wafer W. As shown in FIG. 7, the wafer W is placed on a chuck table 20 in the condition where the back grind tape 10 attached to the front side W1 of the wafer W is in contact with the upper surface of the chuck table 20. Accordingly, the back side W2 of the wafer W placed on the chuck table 20 is oriented upward, or exposed. The upper surface of the chuck table 20 is adapted to hold the wafer W under suction. By applying a suction force to the upper surface of the chuck table 20, the wafer W is held under suction through the back grind tape 10 on the upper surface of the chuck table 20. The chuck table 20 is rotatable about its axis (not shown). In the condition where the wafer W is held on the chuck table 20 under suction, the chuck table 20 is rotated in performing the grinding.

As shown in FIG. 7, the back side W2 of the wafer W held through the back grind tape 10 on the chuck table 20 under suction is ground by using a grinding unit 40. The grinding unit 40 includes a spindle 41 rotatable about its axis (not shown) deviated from the axis of the chuck table 20, a disk-shaped wheel mount 42 fixed to the lower end of the spindle 41, an annular grinding wheel 44 mounted on the lower surface of the wheel mount 42 along its outer circumference, and one or more abrasive members 43 fixed to the lower surface of the grinding wheel 44 so as to be arranged annularly along the outer circumference of the grinding wheel 44. As mentioned above, the axis of the spindle 41 of the grinding unit 40 is deviated from the axis of the chuck table 20. Accordingly, when both the chuck table 20 and the grinding unit 40 are rotated about their respective axes, the back side W2 of the wafer W held on the chuck table 20 can be uniformly ground by the abrasive members 43. Further, the grinding unit 40 is provided with a mechanism for vertically moving the grinding wheel 44 with respect to the chuck table 20, thereby feeding the abrasive members 43 against the back side W2 of the wafer W.

As shown in FIG. 7, the back side W2 of the wafer W held on the chuck table 20 is ground by the abrasive members 43 of the grinding unit 40 until the thickness of the wafer W is reduced to the predetermined finished thickness H. As described above, each groove 30 formed on the front side W1 of the wafer W has a depth corresponding to the finished thickness H. Accordingly, when the thickness of the wafer W is reduced to the finished thickness H by grinding the back side W2 of the wafer W, the bottom of each groove 30 is exposed to the back side W2 of the wafer W. As a result, the separate regions defined by the grooves 30 are divided from each other to obtain individual device chips DT as shown in FIG. 8. During the grinding operation, the front side W1 of the wafer W is held through the back grind tape 10 on the chuck table 20, so that the individual device chips DT are kept attached to the back grind tape 10. Furthermore, each groove 30 has a reverse tapering shape such that the distance d between the opposed side walls 30a is increased from the front side W1 toward the back side W2. Accordingly, in grinding the back side W2 of the wafer W, it is possible to prevent the contact of the opposed side walls 30a at their upper portions on the back side W2 of the wafer W. As a result, it is possible to suppress that the side walls 30a and corners of the adjacent device chips DT may rub each other, thereby obtaining the device chips DT with high quality.

Further, each groove 30 having a depth corresponding to the predetermined finished thickness H is formed on the front side W1 of the wafer W by plasma etching in the preferred embodiment. That is, the wafer W is not divided by the plasma etching. Accordingly, it is possible to suppress that the dicing tape (not shown) attached to the back side W2 of the wafer W may be exposed to the plasma in performing the plasma etching. As a result, damage to the dicing tape by the plasma can be suppressed and it is therefore possible to prevent that foreign matter due to the damage to the dicing tape may be adhere to the wafer W.

After performing the dividing step S5, ultraviolet light having a predetermined wavelength (e.g., 300 to 400 nm) is applied to the back grind tape 10 to thereby reduce the adhesive force of the back grind tape 10. Accordingly, each device chip DT can be easily removed from the back grind tape 10. Thereafter, each device chip DT is transferred to the next step.

In the processing method according to the first preferred embodiment, the groove forming step S2 is performed to form the groove 30 on the front side W1 of the wafer W along each street L, wherein each groove 30 has a depth corresponding to the finished thickness H of each device chip DT. Further, each groove 30 has a reverse tapering shape such that the distance d between the opposed side walls 30a is increased with an increase in depth of each groove 30. With this configuration, in grinding the back side W2 of the wafer W to divide the wafer W into the individual device chips DT, it is possible to suppress that the side walls 30a and corners of the adjacent device chips DT may rub each other, so that each device chip DT can be obtained with high quality. Further, each groove 30 formed on the front side W1 of the wafer W by the plasma etching in the groove forming step S2 has a depth corresponding to the finished thickness H of each device chip DT, and this depth of each groove 30 does not reach the back side W2 of the wafer W. Accordingly, in performing the plasma etching, it is possible to suppress that the dicing tape (not shown) attached to the back side W2 of the wafer W may be exposed to the plasma. As a result, damage to the dicing tape by the plasma can be suppressed and it is therefore possible to prevent that foreign matter due to the damage to the dicing tape may adhere to the wafer W.

### Second Preferred Embodiment

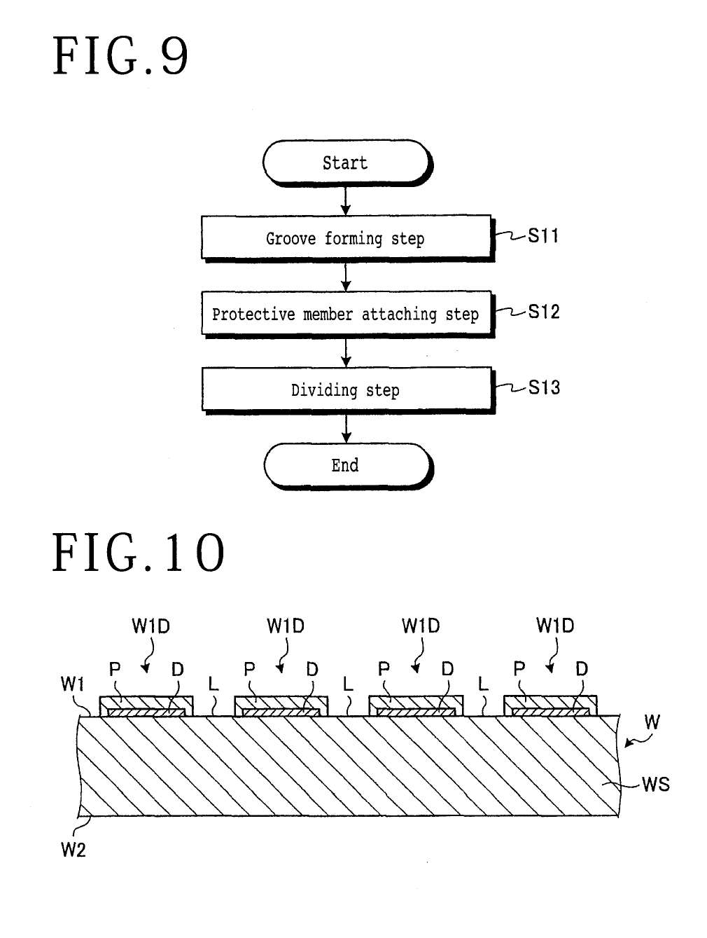

A second preferred embodiment of the present invention will now be described with reference to FIGS. 9 to 14. In the first preferred embodiment, the resist film R as a mask is formed on the front side W1 of the wafer W so as to cover the device corresponding regions W1D corresponding to the devices D formed on the front side W1 of the wafer W. To the contrary, the second preferred embodiment is different from the first preferred embodiment in that a passivation film P is used as a mask in place of the resist film R. FIG. 9 is a flowchart showing the procedure of the device wafer processing method according to the second preferred embodiment. As shown in FIG. 9, the device wafer processing method according to the second preferred embodiment includes a groove forming step S11, a protective member attaching step S12, and a dividing step S13. That is, the second preferred embodiment is different from the first preferred embodiment in that the mask forming step S1 and the mask removing step S3 included in the first preferred embodiment are omitted.

### (Groove Forming Step S11)

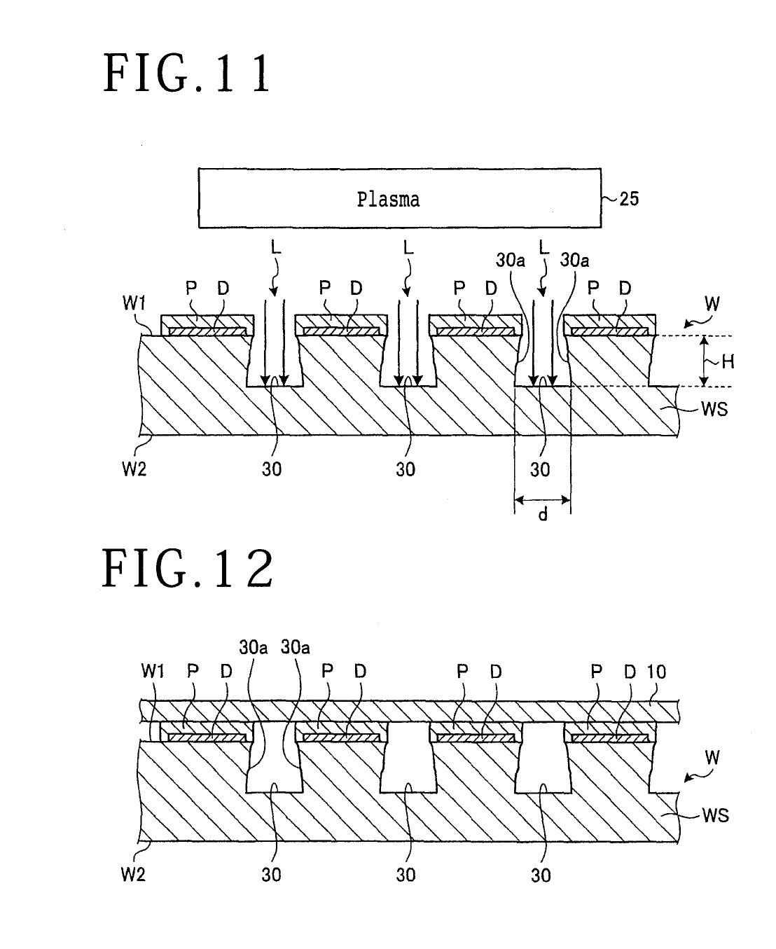

FIG. 10 is a sectional view of the wafer in the condition where the plural devices formed on the front side of the wafer are masked by the passivation film. FIG. 11 is a sectional view showing the groove formed along each street on the front side of the wafer. In general, the passivation film P is formed on the whole surface of the front side W1 of the wafer W. The passivation film P is a protective film formed of silicon nitride, silicon oxide, or polyimide, for example. The passivation film P functions to protect the devices D. However, the passivation film P is formed so as to cover not only the upper surface of each device D, but also the upper surface of each street L. That is, the passivation film P is formed so as to fully cover the front side W1 of the wafer W. The passivation film P is more resistant to etching than the base material of the substrate WS of the wafer W. Therefore, it is preferable to remove the passivation film P from the upper surface of each street L prior to performing the plasma etching, thereby exposing the base material of the substrate WS of the wafer W as shown in FIG. 10.

The passivation film P may be removed from the upper surface of each street L in the following manner. A liquid resin is applied to the front side W1 of the wafer W to thereby form a protective film. Thereafter, a laser beam is applied along each street L to thereby perform ablation to the passivation film P present on each street L. As a result, the passivation film P present on each street L is removed by this ablation and the base material of the substrate WS in the region corresponding to each street L is exposed. Any debris produced by this ablation is prevented from adhering to the upper surface of each device D owing to the presence of the protective film. The method for exposing the base material of the substrate WS in the region corresponding to each street L is not limited to such ablation. For example, cutting using a cutting blade may be performed to each street L, thereby removing the passivation film P present on each street L. Accordingly, the passivation film P is left on the front side W1 of the wafer W so as to cover only the device corresponding regions W1D.

Thereafter, plasma is applied to the front side W1 of the wafer W to thereby form the groove 30 along each street L on the front side W1 of the wafer W, wherein the groove 30 has a depth corresponding to the finished thickness H of each device chip as shown in FIG. 11. Each groove 30 has substantially the same configuration as that in the first preferred embodiment, and the same parts are therefore denoted by the same reference symbols with the description thereof omitted. Further, the method for forming each groove 30 having a reverse tapering shape is also substantially the same as that in the first preferred embodiment, and the description thereof will therefore be omitted.

In the preferred embodiment, the passivation film P present on each street L of the wafer W is removed and the base material of the substrate WS in the region corresponding to each street L is exposed as shown in FIG. 10, so that the upper surface and side surface of each device D is covered with the passivation film P. Accordingly, the passivation film P covering each device D is used as a mask in performing the plasma etching. That is, only the base material of the substrate WS in the region corresponding to each street L is subjected to the plasma etching. The plasma etching is performed under the conditions where the etching rate for the base material of the substrate WS is higher than that for the passivation film P (e.g., the flow rate or kind of an etching gas is suitably selected). In the preferred embodiment, the ratio (selective ratio) of the etching rate for the base material of the substrate WS to the etching rate for the passivation film P is preferably set to 500 or more.

Since the etching rate for the base material of the substrate WS is higher than the etching rate for the passivation film P in the preferred embodiment, the substrate WS is etched faster than the passivation film P, so that the groove 30 is formed along each street L so as to have a depth extending from the front side W1 toward the back side W2 as shown in FIG. 11. The ratio of the etching rate for the base material of the substrate WS to the etching rate for the passivation film P is preferably set so that even when the depth of each groove 30 has reached the finished thickness H, the passivation film P yet has a thickness capable of protecting each device D.

### (Protective Member Attaching Step S12)

FIG. 12 is a sectional view of the wafer in the condition where a back grind tape is attached to the front side of the wafer. After performing the groove forming step S11, a back grind tape (protective member) 10 is attached to the front side W1 (the passivation film P) of the wafer W as shown in FIG. 12. The back grind tape 10 and the protective member attaching step S12 are substantially the same in configuration as those in the first preferred embodiment, and the description thereof will therefore be omitted.

### (Dividing Step S13)

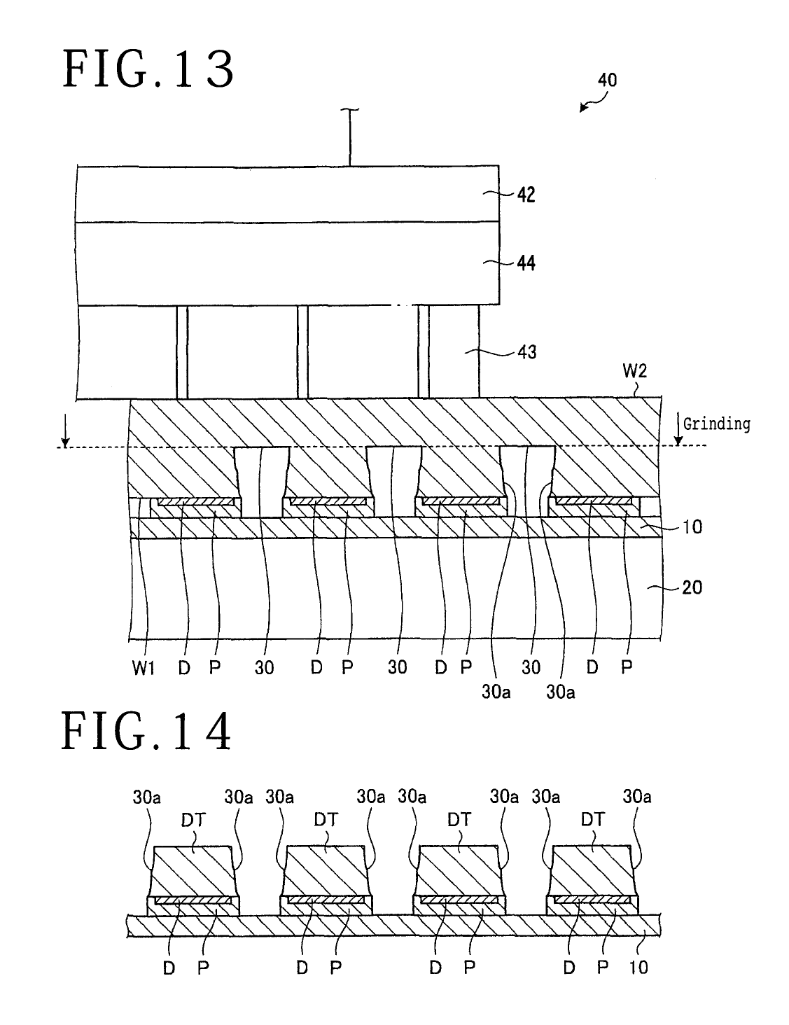

After performing the protective member attaching step S12, a dividing step S13 is performed to grind the back side W2 of the wafer W until the thickness of the wafer W is reduced to the predetermined finished thickness H, thereby dividing the wafer W into the individual device chips. FIG. 13 is a sectional view of the wafer in the condition just before grinding the back side of the wafer. FIG. 14 is a sectional view of the device chips divided from the wafer by grinding the back side of the wafer. The dividing step S13 is substantially the same in configuration as the dividing step S5 in the first preferred embodiment, and the description thereof will therefore be omitted.

In the processing method according to the second preferred embodiment, the groove forming step S11 is performed to form the groove 30 on the front side W1 of the wafer W along each street L, wherein each groove 30 has a depth corresponding to the finished thickness H of each device chip DT. Further, each groove 30 has a reverse tapering shape such that the distance d between the opposed side walls 30a is increased with an increase in depth of each groove 30. With this configuration, in grinding the back side W2 of the wafer W to divide the wafer W into the individual device chips DT, it is possible to suppress that the side walls 30a and corners of the adjacent device chips DT may rub each other, so that each device chip DT can be obtained with high quality. Further, each groove 30 formed on the front side W1 of the wafer W by the plasma etching in the groove forming step S11 has a depth corresponding to the finished thickness H of each device chip DT, and this depth of each groove 30 does not reach the back side W2 of the wafer W. Accordingly, in performing the plasma etching, it is possible to suppress that the dicing tape (not shown) attached to the back side W2 of the wafer W may be exposed to the plasma. As a result, damage to the dicing tape by the plasma can be suppressed and it is therefore possible to prevent that foreign matter due to the damage to the dicing tape may adhere to the wafer W.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A device wafer processing method for processing a device wafer having a substrate and a plurality of devices formed on a front side of said substrate, a plurality of crossing streets being formed on the front side of said substrate to thereby define a plurality of separate regions where said devices are individually formed, said device wafer processing method comprising:
a mask forming step of forming a mask patterned so as to cover said devices and expose the front side of said substrate in a region corresponding to each street;
a groove forming step of applying plasma through said mask to a front side of said wafer to thereby form a groove on the front side of said wafer along each street, said groove having a depth corresponding to a finished thickness of said device and having a reverse tapering shape such that a distance between opposed side walls of said groove is increased with an increase in depth of said groove;
a mask removing step of removing said mask from the front side of said wafer after performing said groove forming step;
a protective member attaching step of attaching a protective member to the front side of said wafer after performing said mask removing step; and
a dividing step of holding the front side of said wafer through said protective member on a chuck table and then grinding a back side of said wafer until a bottom of said groove is exposed to the back side of said wafer, thereby reducing the thickness of said wafer to said finished thickness to divide said wafer into a plurality of device chips.

2. A device wafer processing method for processing a device wafer having a substrate, a plurality of devices formed on a front side of said substrate, and a passivation film covering said devices, a plurality of crossing streets being formed on the front side of said substrate to thereby define a plurality of separate regions where said devices are individually formed, the front side of said substrate in a region corresponding to each street being exposed, said device wafer processing method comprising:
a groove forming step of applying plasma through said passivation film as a mask to a front side of said wafer to thereby form a groove on the front side of said wafer along each street, said groove having a depth corresponding to a finished thickness of said device and having a reverse tapering shape such that a distance between opposed side walls of said groove is increased with an increase in depth of said groove;
a protective member attaching step of attaching a protective member to the front side of said wafer after performing said groove forming step; and
a dividing step of holding the front side of said wafer through said protective member on a chuck table and then grinding a back side of said wafer until a bottom of said groove is exposed to the back side of said wafer, thereby reducing the thickness of said wafer to said finished thickness to divide said wafer into a plurality of device chips.
